(19) United States
(12) Patent Application Publication
(10) Pub. No.: US 2009/0166695 A1
(43) Pub. Date: Jul. 2, 2009

(54) IMAGE SENSOR AND METHOD FOR MANUFACTURING THE SENSOR

(76) Inventor: Seoung-Hyun Kim, Pocheon-si (KR)

Correspondence Address: SHERR & VAUGHN, PLLC, 620 HERNDON PARKWAY, SUITE 200, HERNDON, VA, 20170, US

(21) Appl. No.: 12/344,553

(22) Filed: Dec. 28, 2008

(30) Foreign Application Priority Data
Dec. 31, 2007 (KR) 10-2007-0141447

(51) Int. Cl. H01L 31/112; H01L 31/18

(52) U.S. Cl. 257/292; 438/57; 438/694; 257/E31.079; 257/E21.249

(57) ABSTRACT

A method for manufacturing an image sensor having a peripheral circuit unit and a pixel unit includes forming a device isolation layer that defines an active area in the pixel area, on a semiconductor substrate, forming a gate pattern on the active area of the semiconductor substrate, forming a photodiode area at one side of the gate pattern in the semiconductor substrate, vapor-depositing a plurality of dielectric layers on the whole surface of the substrate including the gate pattern, forming a spacer at lateral sides of the gate pattern by removing part of the plurality of dielectric layers by dry etching, and removing the other dielectric layer disposed between the lowermost dielectric layer and the uppermost dielectric layer by wet etching, while leaving a lowermost dielectric layer among the plurality of dielectric layers on the substrate where a floating diffusion area will be formed.

The present application claims priority under 35 U.S.C. 119 to Korean Patent Application No. 10-2007-0141447 (filed on Dec. 31, 2007), which is hereby incorporated by reference in its entirety.

### BACKGROUND

An image sensor refers to a device that converts an optical signal to an electric signal using photosensitivity of a semiconductor. Image sensors are generally divided into one of two types: a charge coupled device (CCD) and a complementary metal oxide semiconductor (CMOS) image sensor. The CMOS image sensor is equipped with light receiving elements and switching elements corresponding to the number of pixels, and outputs electric signals converted from optical signals using the above elements. The CMOS image sensor can be conveniently operated compared to the CCD, and be compactly formed since a signal processing circuit can be integrated in one chip. Furthermore, due to low power consumption, a battery of the CMOS image sensor has a long lifespan. A CMOS image sensor may include a pixel unit that perceives light and accordingly generates signals, and a peripheral circuit unit that processes the signals. The pixel unit and the peripheral circuit unit typically use a semiconductor device such as a MOS transistor. The pixel unit includes a photodiode as a light receiving element which generates an electron-hole pair (EHP) in response to the light. CMOS image sensors can generally be classified into a 3T-type, a 4T-type, a 5T-type, etc. according to the number of transistors. The 3T-type includes one photodiode and three transistors. The 4T-type includes one photodiode and four transistors.

FIG. 1 is a circuit diagram of a 4T-type CMOS image sensor. FIG. 2 is a layout of a unit pixel of the 4T-type CMOS image sensor of FIG. 1. As shown in FIGS. 1 and 2, the unit pixel includes a photodiode (PD) 10 as an optical converter, and four transistors Tx, Rx, Dx and Sx. More specifically, the four transistors include a transfer transistor (Tx) 20, a reset transistor (Rx) 30, a drive transistor (Dx) 40, and a select transistor (Sx) 50. A drain terminal of the select transistor 50, which is an output terminal of each unit pixel, is electrically connected with a load transistor (not shown).

FIG. 3 is a sectional view of the 4T-type CMOS image sensor of FIGS. 1 and 2. As shown in FIG. 3, the 4T-type CMOS image sensor further includes a P-type semiconductor substrate 70 whereon an active area and a device isolation area are defined, a device isolation layer 72 formed in the device isolation area, a well area formed on and/or over the semiconductor substrate 70, a gate oxide layer 74 and a gate electrode 20 which are formed in sequence on a predetermined portion of the active area, and a spacer 86A formed at one side of the gate oxide layer 74 and the gate electrode 20. The spacer 86A may have a multi-layered structure such as an oxide-nitride-oxide (ONO) structure including an oxide layer 80A, a nitride layer 82A, and an oxide layer 84A. In order to improve a dark defect, dielectric layers 80B, 82B and 84B in the ONO structure are formed on and/or over the other side of the gate electrode 20, to partially cover the photodiode 10 and the gate electrode 20.

However, in the CMOS image sensor as shown in FIG. 3, since the nitride layer 82B is formed on and/or over the photodiode 10, light being incident to the photodiode 10 is partially blocked by the nitride layer 82B. Accordingly, the light receiving characteristics of the photodiode 10 are deteriorated.

Gates of the respective transistors Tx, Rx, Dx and Sx in the 4T-type CMOS image sensor are manufactured in the form of gate electrodes 20, 30, 40 and 50. An N+ well area formed on and/or over the semiconductor device 70 serves as a source and drain area of the respective transistors. Predetermined parts of the N+ well area disposed among the gate electrodes 20, 30, 40 and 50 are defined as a floating diffusion (FD) node 60.

In the above-described CMOS image sensor, during the etching for forming the spacer 86A at one side of the gate electrode 20, an upper surface of the semiconductor substrate 70, whereon the FD node 60 will be formed, is also etched which may cause a significant dark defect. In other words, the ONO-structure layers are vapor-deposited first on and/or over the uppermost surface of the substrate 70 to form the spacer 86A and a mask 86B. Next, the ONO layers are etched by dry etching, thereby forming the spacer 86A at the one side of the gate electrode 20. In this process, however, a silicon lattice at the upper part of the substrate 70 where the FD node 60 will be formed can be attacked by the dry etching, thereby inducing a leakage source and the dark defect.

### SUMMARY

Embodiments relate to an image sensor and a method for manufacturing the image sensor that maximizes the light receiving characteristics of a photodiode while preventing a silicon lattice from being attacked during formation of a spacer.

Embodiments relate to a method for manufacturing an image sensor having a peripheral circuit unit and a pixel unit that may include at least one of the following: forming a device isolation layer on and/or over a semiconductor substrate to define an active area in the pixel unit, forming a gate pattern on and/or over the active area of the semiconductor substrate, forming a photodiode area at one side of the gate pattern in the semiconductor substrate, vapor-depositing a plurality of dielectric layers on and/or over the substrate including the gate pattern, forming a spacer at lateral sides of the gate pattern by removing a portion of the plurality of dielectric layers by dry etching, and removing the other dielectric layer disposed between the lowermost dielectric layer and the uppermost dielectric layer by wet etching, while leaving a lowermost dielectric layer among the plurality of dielectric layers on the substrate where a floating diffusion (FD) area will be formed.

Embodiments relate to a method for manufacturing an image sensor having a peripheral circuit unit and a pixel unit that may include at least one of the following: forming a device isolation layer on and/or over a semiconductor substrate to define an active area in the pixel unit, forming a gate pattern on and/or over the active area of the semiconductor substrate, forming a photodiode area at one side of the gate pattern in the semiconductor substrate, vapor-depositing a plurality of dielectric layers on and/or over the substrate including the gate pattern, and forming a spacer at lateral sides of the gate pattern by partially dry-etching the plurality of dielectric layers while leaving a lowermost dielectric layer among the plurality of dielectric layers on the substrate where the FD area will be formed.

Embodiments relate to an image sensor having that may include at least one of the following: a device isolation layer defining an active area in a pixel area of a semiconductor substrate; a gate pattern formed on and/or over the active area of the semiconductor substrate; a photodiode area formed at one side of the gate pattern in the semiconductor substrate; a spacer formed in multiple layers at lateral sides of the gate pattern; and a dielectric layer formed on and/or over the substrate where an FD area will be formed and connected with a lowermost layer of the spacer.

Embodiments relate to a method that may include at least one of the following: forming a device isolation layer defining an active area in a pixel area of a semiconductor substrate; and then forming a gate pattern over the active area; and then forming a photodiode at one side of the gate pattern in the semiconductor substrate; and then forming a plurality of dielectric layers over the semiconductor substrate including the gate pattern and the photodiode; and then forming a spacer at lateral sides of the gate pattern by removing a portion of the plurality of dielectric layers while not removing a portion of the lowermost dielectric layer of the plurality of dielectric layers formed over a floating diffusion region of the semiconductor substrate.

Embodiments relate to a device that may include at least one of the following: a device isolation layer defining an active area in a pixel area of a semiconductor substrate; a gate pattern formed over the active area; a photodiode formed in the semiconductor substrate adjacent the gate pattern; a spacer having a multi-layered structure formed on at least one side of the gate pattern; and a dielectric layer formed over a floating diffusion region of the semiconductor substrate and connected to the spacer.

Embodiments relate to a device that may include at least one of the following: device isolation layers defining an active area in a pixel area of a semiconductor substrate; a floating diffusion region formed in the semiconductor substrate; a gate pattern formed over the active area; a photodiode formed in the semiconductor substrate adjacent the gate pattern; spacers formed at sidewalls of the gate pattern, the spacer including first, second and third dielectric layers. In accordance with embodiments, the first dielectric layer includes a first portion that forms a portion of each of the spacers, a second portion connected to the first portion and formed over and contacting the uppermost surface of the gate pattern, a third portion connected to the first portion and formed over the floating diffusion region, and a fourth portion connected to the first portion and formed over the photodiode.

### DRAWINGS

FIGS. 1 to 3 illustrate an equivalent circuit diagram, a unit pixel and a sectional view of a 4T-type CMOS image sensor.

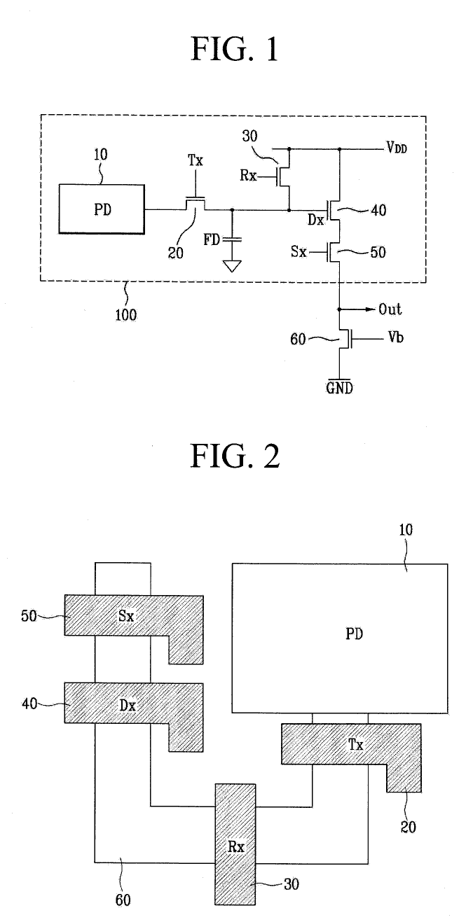

Example FIGS. 4A to 4H illustrate a method of manufacturing an image sensor in accordance with embodiments.

### DESCRIPTION

Example FIGS. 4A to 4H are sectional views illustrating the manufacturing processes of an image sensor, according to embodiments. Referring to example FIG. 4A, a device isolation layer 202 that defines an active area may be formed in a semiconductor substrate 200. The device isolation layer 202 may be formed according to a process such as, for example, etching the semiconductor substrate 200 to form a trench and then filling a dielectric layer in the trench.

Referring to example FIG. 4B, a gate dielectric and a polysilicon layer may then be sequentially formed on and/or over the semiconductor substrate 200 and then patterned, thereby forming a gate pattern in the active area of the substrate 200. An oxide layer can be used as the gate dielectric. The gate pattern includes a gate oxide layer 204 formed by patterning the gate dielectric, and a gate silicon layer 206 formed by patterning the polysilicon layer.

Referring to example FIG. 4C, ions may be implanted in the substrate 200 using the gate patterns 204 and 206 as masks, thereby forming a photodiode 208 therein. Referring to example FIG. 4D, a plurality of dielectric layers 216 are vapor-deposited on and/or over the substrate 200 including the gate patterns 204 and 206. For example, the dielectric layers 216 may have an ONO structure including three layers such as an oxide layer 210, a nitride layer 212, and an oxide layer 214. However, other dielectric layer structures are contemplated as well.

Referring to example FIG. 4E, a portion of the uppermost one of the plural dielectric layers 216, that is, the oxide layer 214, may be removed, for example, by dry etching. As a result, a spacer 214A remains at lateral sides of the gate patterns 204 and 206. Reactive ion etching (RIE) may, for example, be used for the dry etching. When dry-etching the oxide layer 214, the underlying nitride layer 212 may be etched to a predetermined thickness, for example, up to a half of its original thickness.

As shown in example FIG. 4F, the lowermost dielectric layer 210B among the plurality of dielectric layers 216A may be left on and/or over the substrate 200 whereon a floating diffusion (FD) area 218 will be formed. However, a portion of the middle dielectric layer, i.e., the nitride layer 212A, remaining after the dry etching, may be removed, for example, by wet etching. Thus, because the upper portion of the substrate 200 whereon the FD node or the FD area 218 will be formed is covered with the oxide layer 210B, the dark defect can be maximized. In addition, the dielectric layer 212A vapor-deposited on and/or over the substrate 200 including the photodiode area 208 may also be removed by wet etching. As a result, the lowermost dielectric layer 210B remains on the substrate 200 formed with the photodiode area 208.

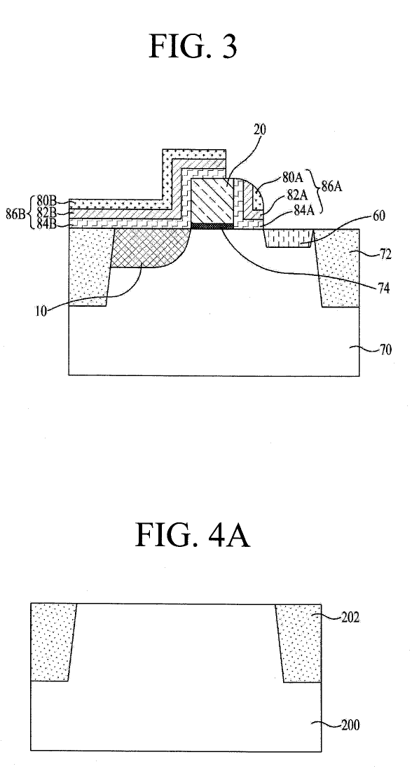

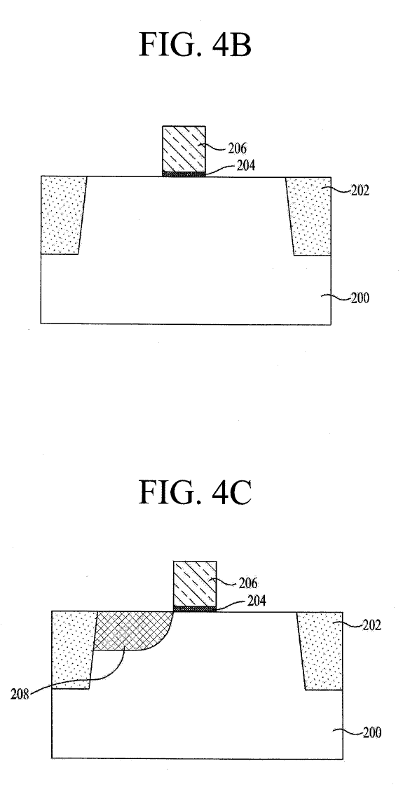

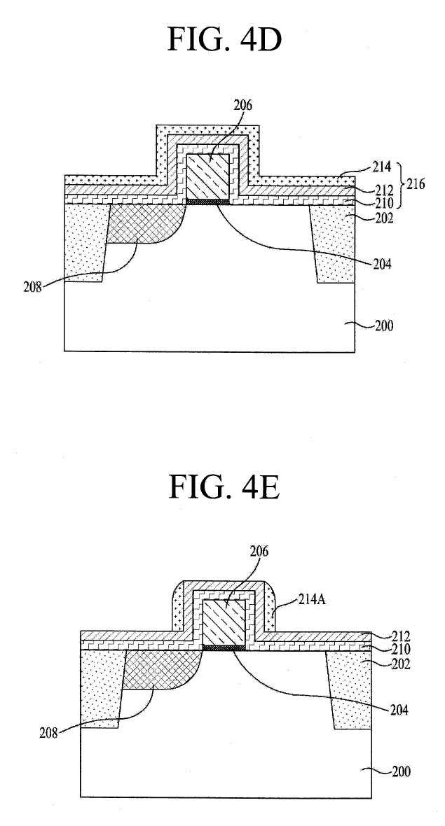

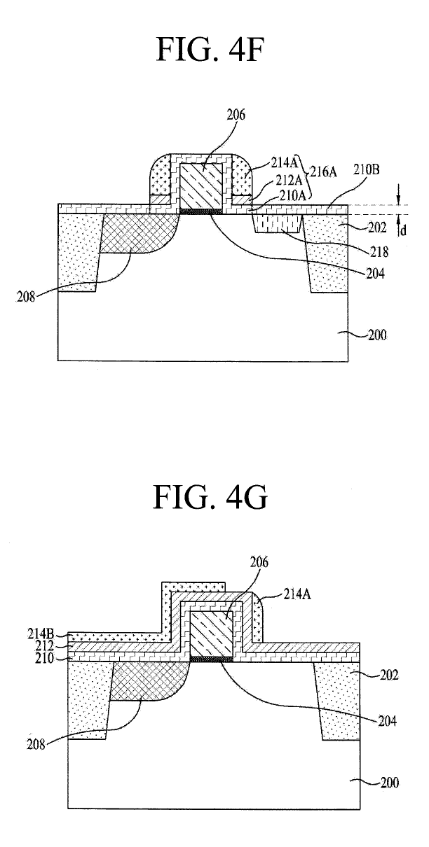

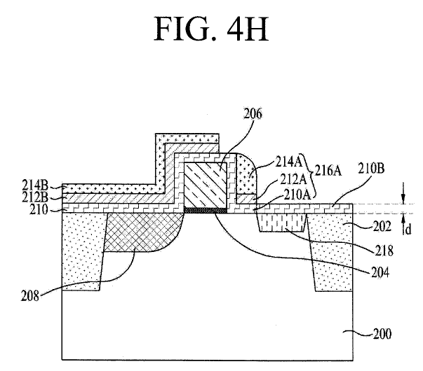

In comparison, the CMOS image sensor shown in FIG. 3 has deteriorated light receiving characteristics because of the nitride layer remaining on and/or over the photodiode. In accordance with embodiments, however, since the nitride layer 212A is removed by wet etching from the photodiode area 208, the intensity of the light incident to the photodiode area 208 is increased. Consequently, the white defect may be improved.

A resultant spacer 216A including the dielectric layers 210A, 212A and 214A may be formed on both sides of the gate patterns 204 and 206 as shown in example FIG. 4F. The lowermost dielectric layer 210 can be formed on and/or over the whole surface of the gate pattern 206 along with removing the dielectric layer 212 by, for example, wet etching.

According to embodiments, after the plurality of dielectric layers 216 are vapor-deposited on and/or over the substrate 200 as shown in example FIG. 4D, the process illustrated in example FIGS. 4G and 4H may be performed instead of the process of example FIGS. 4E and 4F. Referring to example FIG. 4G, the uppermost dielectric layer 214A among the plurality of dielectric layers 216A may be removed by dry etching from one side (e.g., the right side) of the gate patterns 204 and 206. Therefore, a portion 214A of the uppermost dielectric layer 214 constituting the spacer 216A remains at the side of the gate patterns 204 and 206. Also, there remains the uppermost dielectric layer 214B disposed on and/or over the other side (e.g., the left side) of the gate patterns 204 and 206. Thus, the uppermost dielectric layer 214B may extend over only a portion of the gate pattern and 206.

As shown in example FIG. 4H, the dielectric layer 212B (for example, a nitride layer) remaining on and/or over a partial upper side and on the right side of the gate pattern 206 may be removed by wet etching. Accordingly, the dielectric layers 210, 212B and 214B cover the photodiode area 208 on and/or over the left of the gate pattern 206. On the right of the gate pattern 206, the spacer 216A is formed and, in addition, the lowermost dielectric layer 210 covers the FD node 218. As shown in example FIGS. 4G and 4H, therefore, the dry etching and wet etching can be performed with respect only to the plurality of dielectric layers 216A disposed on the right of the gate pattern 206. Since the upper part of the substrate 200 where the FD node 218 will be formed is covered by the oxide layer 210B, the dark defect can be improved.

The wet etching described above may, for example, be performed using a phosphoric acid solution. According to embodiments, when wet etching is used to removing the middle layer 212 (e.g., the nitride layer 212), the thickness of the remaining oxide layer 210 can be adjusted precisely. However, as an alternative, dry etching instead of wet etching may be used to remove the nitride layer 212. More specifically, part of the plurality of dielectric layers 216 in example FIG. 4D, that is, the dielectric layers 212 and 214 may be dry-etched so that the spacer 216A is formed on the side of the gate pattern 206 while the lowermost dielectric layer 210 whereon the FD area 218 will be formed remains on the substrate 200 as shown in example FIGS. 4F and 4H.

In addition, as shown in example, FIG. 4F, the dielectric layer 216A formed on, on or over, the substrate 200 including the photodiode area 208 may be dry-etched so that the lowermost dielectric layer 210B remains on the substrate 200 including the photodiode area 208. When removing the nitride layer 212, wet etching is beneficial for adjusting the thickness of the remaining lowermost dielectric layer 210 more accurately. On the other hand, the lowermost dielectric layer 210 initially vapor-deposited on, or over, the substrate 200 as shown in example FIG. 4D may be partially etched while the dielectric layers 212 and 214 are being etched. The lowermost dielectric layer 210 remaining on the substrate 200, especially on the FD node 218 and the photodiode area 208 may have a thickness of about 10 to about 300 Å.

Referring to example FIG. 4F, the image sensor includes the pixel unit, the device isolation layer 202, the photodiode area 208, the gate oxide layer 204, the gate pattern 206, the spacer 216A, the lowermost dielectric layer 210B, and the FD area 218. Whereas the image sensor in example FIG. 4F has the spacers 216A on both sides of the gate pattern 206, the image sensor in example FIG. 4H has the spacer 216A formed at one side of the gate pattern 206 and the masks 210, 212B and 214B at the other side of the gate pattern 206.

The device isolation layer 202, defining the active area, may be formed in the substrate 200 and the gate oxide layer 204 and the gate pattern 206 may be formed on, or over, the active area of the substrate 200. The photodiode area 208 may formed in the substrate 200 on one side (e.g., the left side) of the gate patterns 204 and 206. The spacer 216A includes multiple layers such as, for example, dielectric layers 210, 212A and 214A formed on the side of the gate patterns 204 and 206. The dielectric layer 210B is formed on and/or over the substrate 200 where the FD area 218 is formed and on and/or over the photodiode area 208, being connected with the lowermost dielectric layer 210A of the spacer 216A. Here, the dielectric layer 210B can be connected with the lowermost dielectric layer 210A of the spacer 216A since the dielectric layers 210A and 210B start from the same layer when the spacer 216A is formed. Thus, in accordance with embodiments, a method for manufacturing an image sensor includes forming an oxide layer on the FD node and a photodiode area during the process of forming a spacer at both sides of a gate pattern. As a result, damage to the FD node during subsequent processing steps may be prevented. Also, by omitting a nitride pattern from the photodiode area, a dark defect and a white defect can be improved, thereby enhancing image sensor sensitivity.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a device isolation layer defining an active area in a pixel area of a semiconductor substrate; and then
forming a gate pattern over the active area; and then
forming a photodiode at one side of the gate pattern in the semiconductor substrate; and then
forming a plurality of dielectric layers over the semiconductor substrate including the gate pattern and the photodiode; and then
forming a spacer at lateral sides of the gate pattern by removing a portion of the plurality of dielectric layers while not removing a portion of the lowermost dielectric layer of the plurality of dielectric layers formed over a floating diffusion region of the semiconductor substrate.

2. The method of claim 1, wherein forming the plurality of dielectric layers comprises vapor-depositing at least one of the plurality of dielectric layers.

3. The method of claim 1, wherein removing a portion of the plurality of dielectric layers is performed by dry-etching.

4. The method of claim 3, wherein a reactive ion etching is performed as the dry etching.

5. The method of claim 4, wherein the reactive ion etching is performed with respect only to one side of the plurality of dielectric layers disposed over the gate pattern.

6. The method of claim 1, wherein after removing a portion of the plurality of dielectric layers, a portion of the lowermost dielectric layer remains over the uppermost surface and sidewalls of the gate pattern.

7. The method of claim 1, wherein after removing a portion of the plurality of dielectric layers, a portion of the lowermost dielectric layer remains over the photodiode.

8. The method of claim 1, wherein the lowermost dielectric layer comprises an oxide layer.

9. The method of claim 1, wherein the plurality of dielectric layers comprises three layers.

10. The method of claim 1, wherein the plurality of dielectric layers comprises an oxide-nitride-oxide structure.

11. A device comprising:
a device isolation layer defining an active area in a pixel area of a semiconductor substrate;
a gate pattern formed over the active area;
a photodiode formed in the semiconductor substrate adjacent the gate pattern;
a spacer having a multi-layered structure formed on at least one side of the gate pattern; and
a dielectric layer formed over a floating diffusion region of the semiconductor substrate and connected to the spacer.

12. The device of claim 11, wherein the multi-layered structure comprises a first oxide layer, a nitride layer and a second oxide layer.

13. The device of claim 11, wherein the dielectric layer has a thickness in a range between approximately 10 Å to 300 Å.

14. The device of claim 11, wherein the dielectric layer is formed over the photodiode.

15. The device of claim 11, wherein the dielectric layer is formed over the uppermost surface and sidewalls of the gate pattern.

16. A device comprising:
device isolation layers defining an active area in a pixel area of a semiconductor substrate;
a floating diffusion region formed in the semiconductor substrate;
a gate pattern formed over the active area;
a photodiode formed in the semiconductor substrate adjacent the gate pattern;
spacers formed at sidewalls of the gate pattern, the spacer including first, second and third dielectric layers,
wherein the first dielectric layer includes a first portion that forms a portion of each of the spacers, a second portion connected to the first portion and formed over and contacting the uppermost surface of the gate pattern, a third portion connected to the first portion and formed over the floating diffusion region, and a fourth portion connected to the first portion and formed over the photodiode.

17. The device of claim 16, wherein the first portion is formed over and contacting the sidewalls of the gate pattern and a portion of the uppermost surface of the semiconductor substrate.

18. The device of claim 16, wherein the first dielectric layer comprises a first oxide layer, the second dielectric layer comprises a nitride layer and the third dielectric layer comprises a second oxide layer.

19. The device of claim 16, wherein the first dielectric layer has a thickness in a range between approximately 10 Å to 300 Å.

20. The device of claim 16, wherein the gate pattern comprises a gate polysilicon layer and an underlying gate oxide layer.
